(19) United States
(12) Patent Application Publication
(10) Pub. No.: US 2017/0086334 A1
(43) Pub. Date: Mar. 23, 2017

(54) VARIABLE REFRIGERANT FLOW MUTLIPOINT DISTRIBUTED CHILLED WATER COOLING AND CONTROL SYSTEM FOR DATA CENTERS

(71) Applicant: Jeffery Lynn Riddle, Richardson, TX (US)

(72) Inventor: Jeffery Lynn Riddle, Richardson, TX (US)

(21) Appl. No.: 14/859,386

(22) Filed: Sep. 21, 2015

(51) Int. Cl. H05K 7/20; F25B 25/00; F24F 12/00; F24F 1/32; F24F 13/30; F25B 49/02; F24F 1/68

(52) U.S. Cl. CPC H05K 7/20781; F25B 49/025; F25B 25/005; F24F 1/68; F24F 1/32; F24F 13/30; F24F 12/00; H05K 7/20745; F24F 11/0012

(57) ABSTRACT

A point to multipoint closed loop chilled water and refrigerant distribution and control system used to distribute chilled water to air handling systems used to supply cold air ventilation to data center rooms and to the electronic equipment mounted therein which require constant cooling by using a control system controlling variable speed pumps, fans, compressors and condensers to operate a closed loop, variable flow refrigerant system and a plurality of associated closed loop water systems working in conjunction with heat exchangers to provide chilled water to interior air handling systems, provide hot water to heating applications and to provide radiant heat or forced air heating to other occupied spaces where desirable within a building containing a data center.

### CROSS-REFERENCE TO RELATED APPLICATION 35 USC §119(e)

Not Applicable

### FIELD OF INVENTION

This invention relates to the assembly and integration of Variable Refrigerant Flow (VRF) inverter compressors, variable speed pumps, valves, heat exchanges, control modules, sensors and closed loop water and refrigerant piping into a single cabinet to be installed and operated within a data center to provide point to multipoint distributed chilled water to various air handling systems located within a data center used to provide air conditioning throughout the data center room. The invention also includes a method of redistributing heat available and collected within the data center to generate hot water and transferable heat to supply air handling systems usable for temperature control in other locations, where heat supply is desirable within a building containing a data center.

### BACKGROUND OF INVENTION

For many decades now telecommunications, cable television and large scale information services companies have constructed and operated “data” centers as central nodes for housing equipment, interconnecting voice and data circuits and storing information in large databases. These data centers have evolved from telephone switching centers and large scale computer rooms to modern day “server farms”.

Equipment miniaturization has increased the density of data traffic served by a single chip, computer processor and server array. Increases in fiber optic cable capacity, wireless network expansion and over-all density in deployment of broadband facilities which interconnect buildings, networks and people has increased the number of data centers and the density of equipment housed within these data center facilities.

Several standards for building and operating data centers exist and one of the standards is the control of the ambient air temperature within the data center which is integral in cooling of the electronics. The present invention introduces a new configuration for using chilled water to supply air handlers used to cool the data center environment.

Traditionally, chilled water cooling systems were designed to operate on/off and thus are not efficient at partial loads. Existing facilities may need more chilled water cooling but have limited space for additional system components. The piping and ducting for typical systems is large and requires use of flame/welding to install.

Existing heat loads can be located inside a facility, which often times may be too far from the outside location of compressor and condenser equipment to be economically served by conventional systems.

The system in the present embodiment integrates Variable Refrigerant Flow (VRF) components with a small chilled water loop to: 1) Provide efficient cooling at all load conditions; 2) Eliminate the need for large piping and ducting as well as flame free installation; 3) allow long runs of refrigerant piping to reach existing heat loads.

Therefore, a very real purpose is served by the present invention which integrates the cooling and power control within a server rack cabinet without altering the standard shape and dimension of the cabinet as it is dimensioned today. By integrating these common systems into the server rack cabinet, the range of possibilities for use of the system greatly increases since the room or location for housing such a cabinet does not require any special modification or equipment to control ambient environmental conditions or power source.

The present invention simplifies the deployment of multipoint distributed chilled water cooling systems within the data center. In short, the present invention works equally well in either a primary system or auxiliary system within the data center.

Although there are several apparatuses which may have various functions related to the variable refrigerant flow multipoint distributed chilled water cooling and control system for data centers, none of these either separately or in combination with each other, teach or anticipate the current invention. Therefore, there remains an unmet need in the field of data center cooling. The current invention will fulfill this unmet need.

### SUMMARY OF INVENTION

The following presents a simplified summary in order to provide a basic understanding of some aspects of the disclosed invention. This summary is not an extensive overview, and it is not intended to identify key/critical elements or to delineate the scope thereof. Its sole purpose is to present some concepts in a simplified form as a prelude to the more detailed description that is presented later.

The present embodiment presents a multipoint distributed chilled water cooling and control system consisting of integrated variable speed pumps, valves, heat exchanges, control modules, sensors and closed loop water and refrigerant piping into a single cabinet located within a data center provides data center operators greater flexibility in deploying electronics requiring rack mounts, temperature control and power reliability. A cabinet must be compatible with standard line-ups, cabling systems and clearances required when deploying cabinets in new or existing data centers, remote nodes or equipment closets. The present invention provides for an integrated cooling and control package which remains compatible with traditional dimensions of equipment cabinet and is therefore compatible during new installations or as expansion to existing installations.

For applications not subject to standard line-ups or other limitations, the present embodiment is not constrained by such standard dimensions and may be deployed in cabinets or enclosures of different dimensions without compromising the functionality of the system described herein.

The present embodiment is a system which integrates Variable Refrigerant Flow (VRF) components with a small chilled water loop to: 1) Provide efficient cooling at all load conditions; 2) Eliminate the need for large piping and ducting as well as flame free installation; 3) allow long runs of refrigerant piping to reach existing heat loads.

This system shown in the present embodiment varies its energy use with the heat load and is more efficient at partial loads. It requires no large piping or ducting and no open flame welding. It is also capable of supplying cooling to locations within a facility that cannot be reached by typical systems.

The VRF Inverter Compressor Condenser(s) utilized in the present embodiment are required to enable the system to vary its capacity to the heat load. Refrigerant to water heat exchangers are critical to the operation and integration of the system. The variable speed pump allows water to be pumped at flow rates that match the flow required by the facility cooling equipment (Heat Load). Small diameter copper piping runs connected with compression fittings are essential to enabling system installation in congested facilities with no welding/flame.

The present embodiment consisting of components in the system to remove heat from a facility in a unique way by integrating a VRF refrigerant system with a small chilled water loop. The process begins when heat is generated by facility equipment (heat load) such as a computer server rack. This heat is transferred to the water within the closed loop water piping which is circulated by a variable speed pump which is located as close to the heat load as possible making the piping small and compact which eliminates the use of steel pipe, open flame welding and ducting. The closed chilled water loop is constructed using small copper piping.

When the water in the chilled water loop enters the heat exchangers it transfers the heat from the water to the refrigerant (R410A) before leaving the heat exchanger. The refrigerant then flows through the closed loop refrigerant loop, which is constructed using copper piping, less than two (2) inch diameter with compression fittings. This piping loop is minimally invasive and can be run above ceilings, behind walls and around existing obstructions to the Out Door Units (ODUs) outside the facility. The ODUs receive the refrigerant and pump it through condenser coil(s) where the heat is finally transferred to the outside air. Inside the ODUs are inverter compressor/pump(s) that vary capacity (motor speed) by sensing the heat load in the chilled water loop and the current environmental conditions outside. It does this to modulate cooling capacity. Capacity then matches the heat load demand at the server and uses ambient cooling to reduce energy consumption.

The present embodiment consists of ODUs with VRF inverter compressor and corresponding condenser(s) which are installed outside the facility. The heat exchanger and associated chilled water pumping system are located inside the facility. The copper piping loops for refrigerant run from connection points located at the ODUs VFR to the connections points at the heat exchanger. Piping can connected using compression fittings which eliminate the need for using open flame brazing.

Chilled water piping loops run from connection points at the combined heat exchanger chilled water pumping system to connection points at the facility air handling equipment (Heat Load). Chilled water piping is connected to the supply and return ports provided. This piping consists of copper and is sized using standard engineering calculations to assure adequate water flow to the facility air handling equipment (Heat Load). The multipoint distributed chilled water network consists of multiple heat exchangers connected to multiple chilled water loops connected to multiple air handler systems where each chilled water loop within the data center is isolated.

The systems within the present embodiment must then be connected to electrical power per the electrical specifications of each component. After the systems are installed and tested they are commissioned by authorized personnel.

The system presented also consists of the Heat Exchanger/Chilled Water Pumping System. The Heat Exchanger/Chilled Water Pumping System is built by assembling a number of heat exchangers and a variable speed water pump into a compact enclosure or rack. The heat exchangers are connected to the pump via a piping network and controlled by automatic valves. Sensors are installed which measure water temp and flow as well as refrigerant temp, flow and pressure. These measurement data are sent to the automatic valves, the water pump and the ODUs to signal necessary changes in capacity (compressor speed).

The facility equipment (heat load) to be cooled by the system shown in the present embodiment should be identified and the required cooling capacity calculated. Then the system is sized and configured to deliver the required flow rate and water temperature. The system components are delivered to the site. Locations and points of connection are verified and the system is installed per the method above. Startup and commissioning verifies system function.

By reversing the refrigerant flow to the heat exchangers the system can provide hot water for heating needs. The system can be applied in any industry where there are heat loads within congested facilities.

Typical systems have piping that requires open flame welding to install. This system does not require such open flame welding. Also, other methods do not efficiently adjust energy use with the heat load. They require using large piping and/or ducting while this system uses small diameter piping only.

The logic required to make the system presented in the present embodiment work efficiently and seamlessly is programmed into the controls. Data from various sensors is used as follows:
Outdoor air temp increasing=Compressor/Condenser speed increasing
Outdoor air temp decreasing=Compressor/Condenser speed decreasing
Return water temp increasing=Compressor/Condenser speed increasing
Return water temp decreasing=Compressor/Condenser speed decreasing
Return water temp increasing=Additional Heat Exchanger(s) online
Return water temp decreasing=Additional Heat Exchanger(s) offline
Chilled water demand (GPM) increasing=Pump speed increasing
Chilled water demand (GPM) decreasing=Pump speed decreasing

Still other objects of the present invention will become readily apparent to those skilled in this art from the following description wherein there is shown and described the embodiments of this invention, simply by way of illustration of the best modes suited to carry out the invention. As it will be realized, the invention is capable of other different embodiments and its several details are capable of modifications in various obvious aspects all without departing from the scope of the invention. Accordingly, the drawing and descriptions will be regarded as illustrative in nature and not as restrictive.

### BRIEF DESCRIPTION OF THE DRAWINGS

Various exemplary embodiments of this invention will be described in detail, wherein like reference numerals refer to identical or similar components, with reference to the following figures, wherein:

FIG. 1 is a perspective view of preferred embodiment illustrating a datacenter application.

FIG. 3 is a perspective view of preferred embodiment illustrating the cabinet configuration rear.

FIG. 4 is a perspective view of the preferred embodiment illustrating cabinet configuration front.

FIG. 5 is a perspective view of the preferred embodiment illustrating the cabinet configuration side.

FIG. 6 is an exploded view of the preferred embodiment cabinet and components.

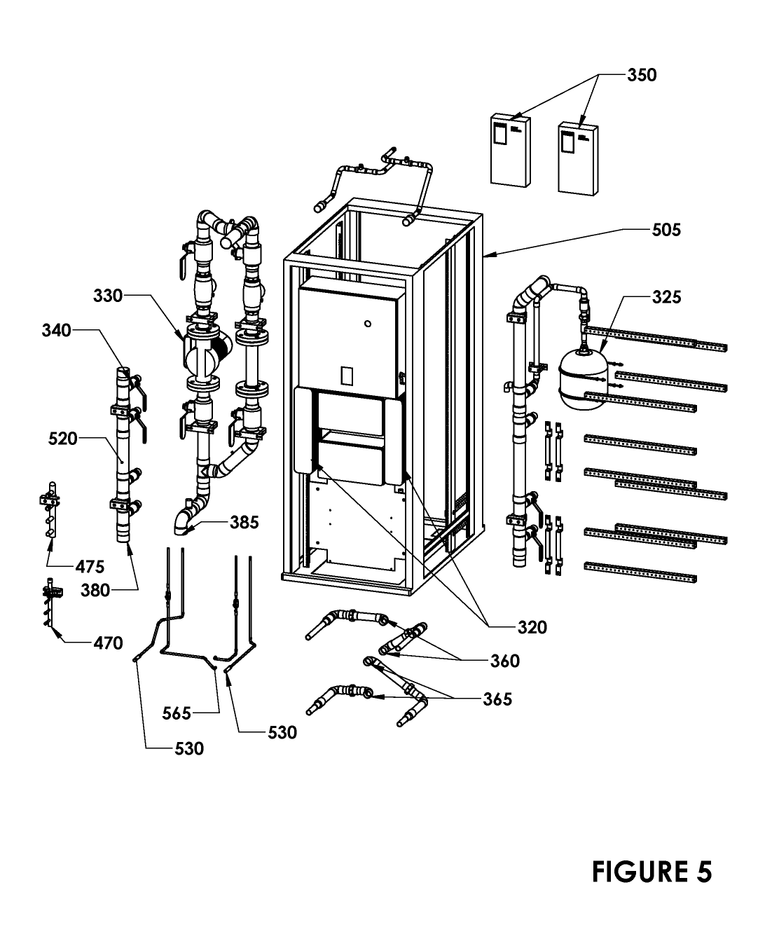

### DETAILED DESCRIPTION

The claimed subject matter is now described with reference to the drawings. In the following description, for purposes of explanation, numerous specific details are set forth in order to provide a thorough understanding of the claimed subject matter. It may be evident; however, that the claimed subject matter may be practiced with or without any combination of these specific details, without departing from the spirit and scope of this invention and the claims.

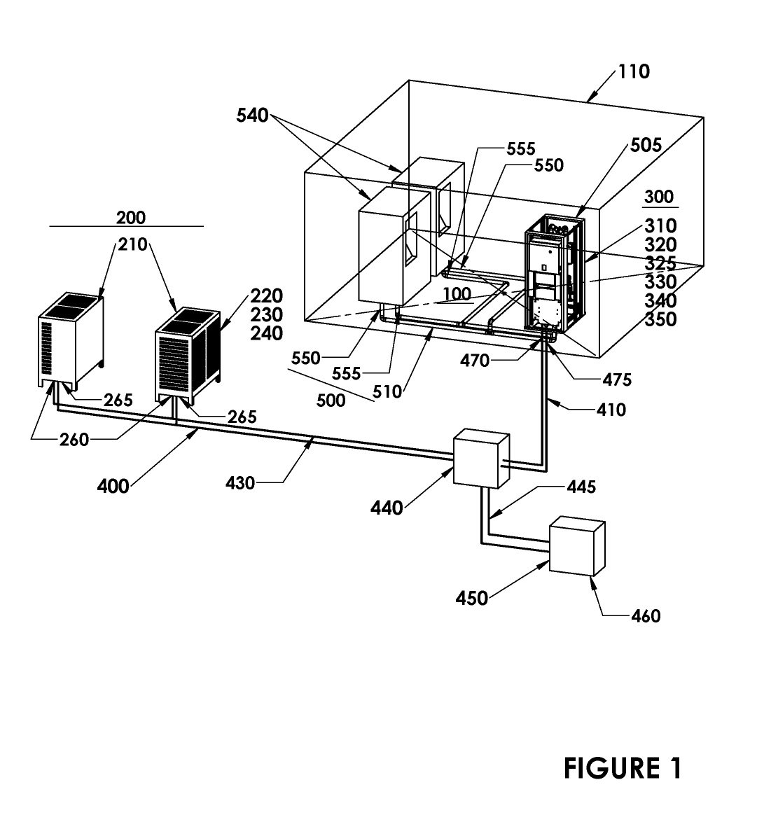

The present embodiment shown in FIG. 1 can be understood by looking at five sub-sections: 1) Outdoor system 200; 2) Indoor system 300; 3) closed loop refrigerant piping 400; 4) indoor chilled water piping 500; and, 5) auxiliary heat recovery system 440.

In FIG. 1, application of the multipoint distributed chilled water cooling and control system 100 is illustrated by showing the data center envelop 110 which is the volume of space defined as the data center to be cooled.

FIG. 1 presents illustration of the outdoor sub-system 200 which contains the outdoor units 210 which contains the inverter compressor 220, condenser 230 and variable speed fans 240. These sub-system components can be operated with or without redundancy and are controlled by the control system 350.

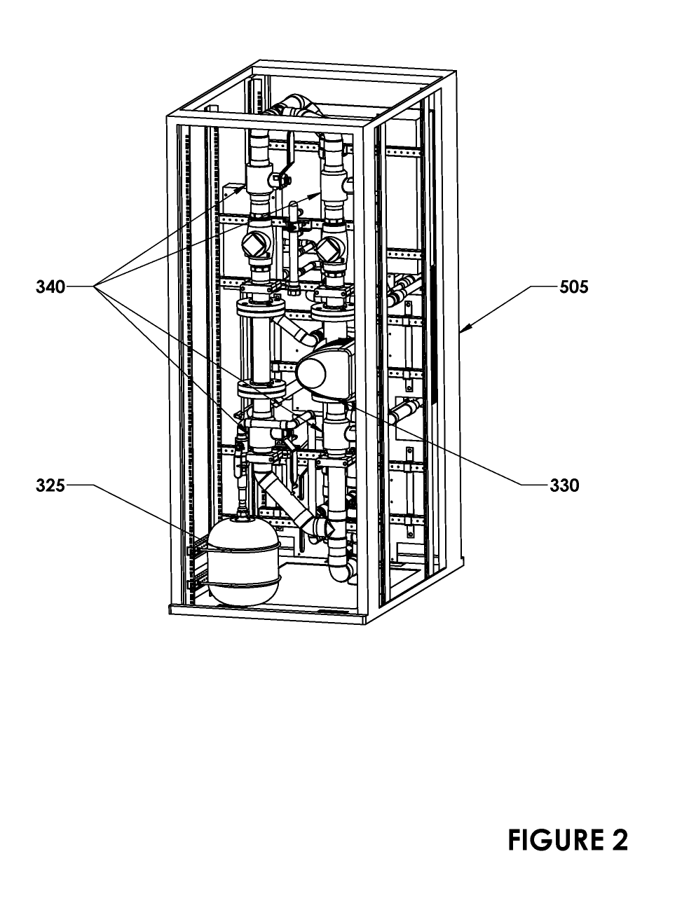

FIG. 1 also presents illustration of the closed loop refrigerant piping system 400 which consists of small diameter pipe 410, long runs 430, heat recovery box 440, water heater 450 and air heater 460. The supply side of the closed loop refrigerant piping small diameter pipe 410 is connected to the heat exchanger 320, shown in FIG. 3, at connection point 470, FIG. 1. The supply side of the closed loop refrigerant piping small diameter pipe 410 is connected to the inverter compressor 220 at connection point 260. The long runs 430 consist of small diameter pipe 410 and connect the heat exchanger 320 to the compressor 220 and condenser 230.

As shown in FIG. 1, the return side of the closed loop refrigerant piping small diameter pipe 410 is connected to the heat exchanger 320 at connection point 475. The supply side of the closed loop refrigerant piping small diameter pipe 410 is connected to the inverter compressor 220 at connection point 265.

FIG. 1 also shows the heat recovery box 440 connected to the auxiliary water heater 450 and auxiliary air heater 460 using auxiliary refrigerant distribution lines 445.

In FIG. 1, the data center envelop 110 is shown which contains the indoor system 300 and closed loop chilled water piping system 500.

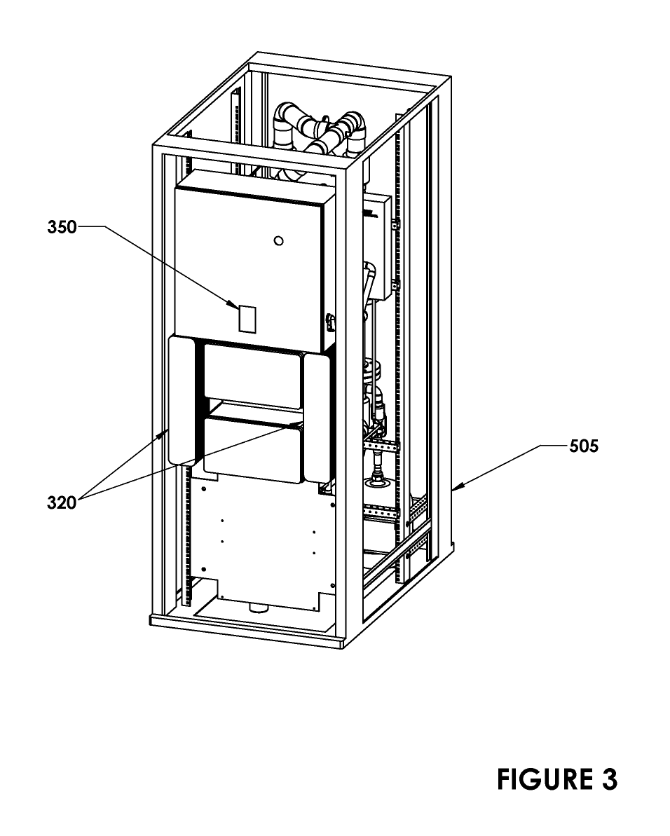

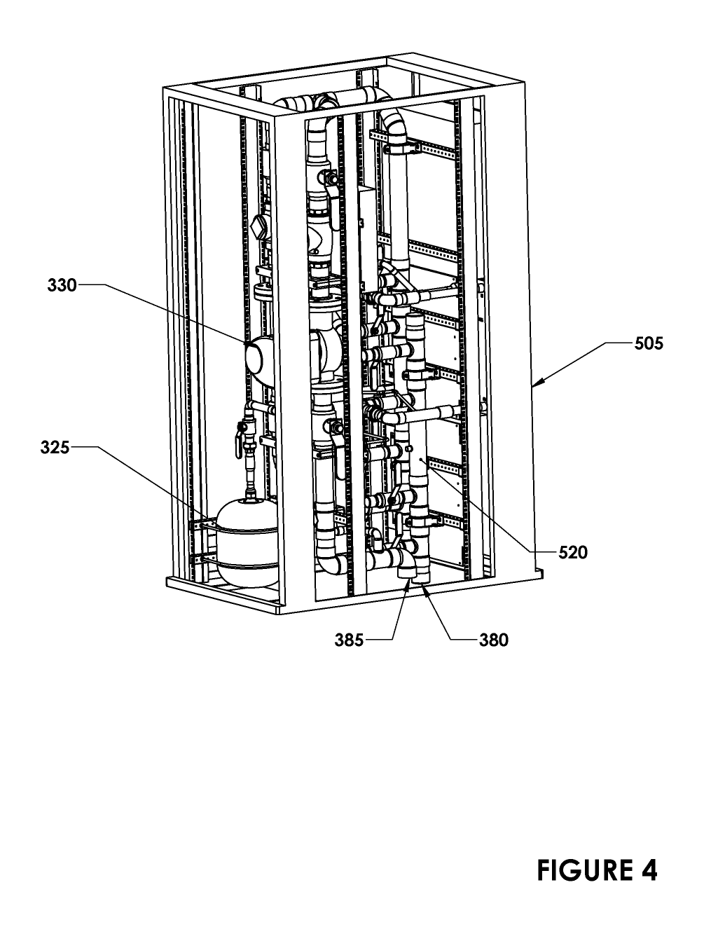

FIG. 1 also presents illustration of the indoor sub-system 300 which contains the indoor chiller unit 310 which is a cabinet 505 containing heat exchangers 320, variable speed pump 330, control valves 340, routing piping 520 and the control system 350, also shown in FIG. 2, FIG. 3, FIG. 4 and FIG. 5. A plurality of heat exchanges 320, FIG. 3, can be connected to control valves 340 FIG. 2 to supply a plurality of closed loop chill water piping distribution lines 510 FIG. 1 to create a point to multipoint distribution system within the data center envelope 110.

The distribution line for the supply side of the closed loop chilled water piping 510 is connected the distribution end of the routing piping 520 FIG. 4 located in cabinet 505 at connection point 380. The distribution line for the supply side of the closed loop chilled water piping 510 FIG. 1 is connected to the heat load 540 at connection point 550.

The distribution line for the return side of the closed loop chilled water piping 510 is connected to the distribution end of the routing piping 520 FIG. 4 located in the cabinet 505 at connection point 385. The distribution line for the return side of the closed loop chilled water 510 is connected to the heat load 540 at connection point 555.

The supply side of the routing piping 520 is connected to the heat exchanger 320 at connection point 360. The return side of the routing piping 520 is connected to the heat exchanger 320 at connection point 365 using fitting 530.

In FIG. 5, the routing piping 520 interconnects the heat exchanger 320 to the variable speed pump 330 and control valves 340 which are controlled by the control system 350. The volume of water circulating in the closed loop chilled water piping system 500 is control directly by adjusting the speed of the variable speed pump 330 by the control system 350. The volume to chilled water circulating is directly proportional to the cooling capacity available to the heat load 540, FIG. 1. Increasing the volume of chilled water circulating provides higher capacity to maintain the temperature of the data center envelop 110 constant when higher heat load 540 is present.

In FIG. 1, the control system 350 also provides control to the outdoor system 200 controlling the inverter compressor 220, condenser 230 and variable speed fans 240. This combined control of outdoor system 200 and indoor system 300 provides operating efficiencies which are not found in other systems. The control system 350 operates to ensure the outdoor system 200 is operating at the most efficient speed to yield the optimum level of heat transfer from the refrigerant contained with the closed loop refrigerant line which was absorbed through the heat exchanger 320. Simultaneously, the control system 350 is controlling the volume of chilled water circulating to the heat load 540 through the heat exchanger 320 to maximize the level of heat transfer from the chilled water to the refrigerant. The control system 350 adjusts the speed of the variable speed components contained within both the indoor system 300 and outdoor system 200 to yield the maximum capacity for heat transfer with minimum demand for consumable services such as power consumption and wear on friction bearings contained within the pumps and fans.

It may be advantageous to set forth definitions of certain words and phrases used in this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

What has been described above includes examples of the claimed subject matter. It is, of course, not possible to describe every conceivable combination of components or methodologies for purposes of describing the claimed subject matter, but one of ordinary skill in the art can recognize that many further combinations and permutations of such matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

We claim:

1. An integrated variable speed closed loop point to multipoint chilled water distribution and control system used to supply chilled water to interior air handling systems to cool and distribute air within data centers consisting of:
variable speed pump; and,
variable speed fan; and,
variable speed compressor; and,
a condenser; and,
a closed variable flow refrigerant loop; and,
a plurality of closed water loops; and,
a plurality of heat exchangers; and,
valves; and,
a control system;

2. The multipoint chilled water distribution system in claim 1 with an electronic system for controlling cooling with a data center or auxiliary space comprising:
A memory storing instructions; and,
at least one processor configured to execute the instructions; and,
at least one sensor(s) to detect air temperature within the cabinet; and,
at least one sensor(s) to detect proper operation of the chilled water distribution system; and,
A management system to detect and generate a response to activate air cooling system; chilled water distribution system, generate a response to activate and control fan, pump, compressor and condenser speed; generate a response to control valves through which chilled water and refrigerant flow; generate a response to control variable controls of operation of the variable cooling system; and, generate a response to maintain operation of the integrated systems to achieve cost efficiencies of the operational system.

3. The chilled water distribution system in claim 1, consisting of a closed refrigerant loop consisting of a supply and return side, wherein the return side of the refrigerant loop is used to transfer heat generated by the data center electronic equipment to heat water and adjacent occupied space.

4. The chilled water distribution system in claim 1, with variable speed pump, valves, heat exchangers and control system mounted within a standard server rack.
